(19) United States
(12) Patent Application Publication
(10) Pub. No.: US 2009/0039929 A1
(43) Pub. Date: Feb. 12, 2009

(54) Method to Reduce Static Phase Errors and Reference Spurs in Charge Pumps

(75) Inventor: Marcel A. Kossel, Reichenburg (CH)

Correspondence Address: CANTOR COLBURN LLP-IBM YORKTOWN, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/834,045

(22) Filed: Aug. 6, 2007

(51) Int. Cl. H03L 7/06; G06F 1/00

(52) U.S. Cl. 327/157; 713/500

(57) ABSTRACT

A phase-locked-loop (PLL) circuit, that includes: a differential phase-frequency detector, a charge pump and at least one logical gate disposed therebetween for providing cancellation of pulses of a substantially equivalent value output by the detector to the charge pump; wherein the at least one logical gate receives the detector output signals and generates control signals for the charge pump such that the pulses of substantially equivalent value are eliminated.

### BACKGROUND OF THE INVENTION

1. Field of the Invention

The teachings herein are related to phase-locked-loop (PLL) or delay-locked loop (DLL) circuits, and in particular to techniques for preventing charge feed-through in a charge pump.

2. Description of the Related Art

Analog PLL circuits are generally built of a phase detector, low pass filter and voltage-controlled oscillator (VCO) placed in a negative feedback configuration. There may be a frequency divider in the feedback path or in the reference path, or both, in order to make an output clock of the PLL an integer multiple of the reference path.

Aspects of PLL circuits are discussed in general terms in Wikipedia, an online encyclopedia. Portions of this description of related art are derived from content therein.

The oscillator generates a periodic output signal. Assume that the oscillator is at nearly the same frequency as the reference signal. Then, if the phase from the oscillator falls behind that of the reference, the phase detector causes the charge pump to change the control voltage, so that the oscillator speeds up. Likewise, if the phase creeps ahead of the reference signal, the phase detector causes the charge pump to change the control voltage to slow down the oscillator. The low-pass filter smoothes out the abrupt control inputs from the charge pump. Since the oscillator may be far from the reference frequency, practical phase detectors may also respond to frequency differences, so as to increase the lock-in range of allowable inputs.

An important part of a phase-locked loop is the phase detector. This compares the phase of two inputs to the detector and outputs a corrective signal to control the oscillator such that the phase between the two inputs becomes zero. The two inputs of the phase detector are usually the reference and the divided output of the local oscillator.

There are several types of phase detectors. The simplest is an exclusive OR gate, which maintains a 90° phase difference, but cannot lock the signal unless it is already near frequency. A more complex phase detector uses a simple state machine to determine which of the two signals has a zero-crossing earlier or more often. This brings the PLL into lock even when it is off frequency. This type is known as a Phase Frequency Detector.

A four-quadrant multiplier, also known as a mixer can be used as a phase detector. By multiplying the oscillator and the reference signals, this generates an output consisting of a low-frequency signal whose amplitude is related to the phase difference, or phase error, between the oscillator and the reference, and a second unwanted signal at twice the oscillator frequency that is eliminated by a low-pass filter.

A PLL with a bang-bang charge pump phase detector supplies current pulses with fixed total charge, either positive or negative, to the capacitor acting as an integrator. A phase detector for a bang-bang charge pump must always have a dead band where the phases of the reference and feedback clocks are close enough that the detector fires either both or neither of the charge pumps, for no total effect. Bang-bang phase detectors are simple, but are associated with significant minimum peak-to-peak jitter, because once in lock the phase offset drifts inside the two extrema values of the dead band without triggering any corrections.

A proportional phase detector directs the charge pump to supply charge amounts in proportion to the phase error detected. Although some proportional phase detectors have dead bands, some do not. Specifically, some designs produce both “up” and “down” control pulses even when the phase offset is zero. These pulses are small, nominally the same duration, and cause the charge pump to produce equal-charge positive and negative current pulses when the phase is perfectly matched. These pulses are also known as “equal value pulses” because they always have the same pulse width regardless of the actual phase difference of the phase detector input signals. The pulse width of these short pulses is solely determined by the reset signal delay within the phase detector, which is commonly known as dead zone. If the phase difference of the phase detector input signals is larger than the dead zone, only either the up or the dn output produces equal value pulses. In the case where the phase difference is smaller than the dead zone, both outputs have equal value pulses. The pulse width of the short pulse does not contain any information about the phase relationship at the input of the phase detector. The actual information about the phase difference of the phase detector input signals is contained in the difference of the pulse width of the long pulse minus the pulse width of the short pulse. From that point of view the width of the short pulse—which by the way is also implicitly contained in the long pulse—does not matter for obtaining the actual phase relationship information as long as the charge pump and all other loop components are ideal. However, if the inputs are slightly mismatched, either the up or down pulse will contain slightly more charge than the other and the PLL needs to correct that mismatch. During the pulse width of the short pulses both charge pump paths—the sourcing and sinking path—are active and may lead to a deteriorated performance (charge feed-through, ripples, increased phase noise and jitter) if some loop components are non-ideal. The prevention of such performance degradation is the motivation for canceling the short pulses in the control signals from the phase detector to the charge pump.

Static phase errors—defined as the residual phase error of the input signals of the phase detector when the PLL is in the locked state—may lead to severe phase noise degradation and jitter peaking in PLL circuits. There are roughly three sources of static phase errors. First, there is charge feed-through in the charge pump. Second of all, there is charge pump mismatch. More specifically, current sourcing and sinking in the charge pump is not sufficiently matched (e.g. because of different threshold voltages and electron mobility of the PMOS and NMOS current sources). In addition, there is leakage in the loop filter.

The modeling of all these effects is extremely difficult. But at the same time these sources also belong to the most frequently occurring root-causes of PLL failure and performance degradation. A better understanding of these issues can be gained with reference to FIG. 1.

FIG. 1 illustrates the problem of the charge feed-through in more detail. Phase-frequency detectors (PFD) are typically composed of two resetable D-flip flops or latches operated in parallel and some combinatorial logic to generate the reset pulses. The outputs of the PFD typically consist of a long pulse that indicates the phase difference also known as phase error—of the input signals (f_{ref} and f_{vco}) and a short pulse that represents a reset pulse, which is also denoted in the following description as equal value pulse or substantially equivalent value output. For instance if f_{ref} lags f_{vco}, the phase error pulse occurs at the up-output while the reset pulse is at the dn-output or vice versa if f_{ref} leads f_{vco}. At a differential phase-frequency detector there are differential outputs, referred to as: upp, upn and dnp, dnn.

The signal trace ‘dnp’ contains the equal value pulses, while ‘upp’ contains the long pulses. The difference in width between the long pulse and the short (reset or equal value) pulse represents the phase error (=Phase difference between f_{ref} and f_{vco}). The occurrence of the equal value pulses may lead to charge feed-through because the cascaded switches are closed simultaneously during the pulse width of the equal value pulses. The up and down signals are differential (upp, upn and dnp, dnn).

When the differential outputs of the PFD are used as control signals for an H-bridge charge pump as shown in FIG. 1, it becomes clear as indicated in the timing diagram that each pair of cascaded switches gets simultaneously closed during the period of time of the reset pulse width. It may easily occur that charge from the loop filter get lost if the PMOS and NMOS current sources of the charge pump do not source or sink exactly the same amount of current. This is commonly referred to as charge feed-through and is also closely related to the charge pump mismatch phenomena. In the spectral domain, static phase errors can be seen as reference spurs.

There are various methods that have been applied in prior art circuits to address the charge feed-through problem previously described. Each of the following prior-art methods can either be applied separately or in combination with each other. A first method includes designing the charge pump current sources for zero mismatch (only theoretically achievable at Vdd/2 in the nominal corner). A second method uses dummy charge pump branches with unity gain buffers that control a replica biasing loop of the tail current sources in the charge pump. A third prior art method calls for extending the loop filter with an additional RC section to suppress the resulting reference spurs (commonly only 2nd order loop filters are applied).

An example of a prior-art circuit that makes use of the first and second methods is shown in FIG. 2. The prior art circuit uses unity gain buffers that force the unused branches of the charge pump outputs to have the same common mode voltages as the main outputs, thus removing systematic mismatch that would arise from operation with unequal drain-source voltages of the PMOS and NMOS tail current sources. Supplementing that strategy is a replica bias loop, whose output voltage is compared with the voltage at the unused output of the charge pump.

The prior-art method has a couple of drawbacks. The first drawback is that the charge feed-through cancellation circuit represented by the unity gain buffers can only be operated accurately in a certain operation point (e.g. at Vdd/2 and nominal corner). Typically, unity gain buffers do not work from rail-to-rail as opposed to the charge pump itself and therefore the cancellation accuracy is highly dependent on the actual loop filter voltage and the process corner and temperature. Moreover, the design complexity of the whole feedback loop (replica biasing+unity gain buffers) is rather complex. Compared to all the rest of the charge pump design, the feedback loop design also consumes a significant amount of power and silicon area.

What are needed are techniques for reducing static phase errors and reference spurs in a PLL or DLL circuit. Preferably, the techniques consume minimal power. Exemplary techniques meeting these and other needs are provided herein.

### SUMMARY OF THE INVENTION

The shortcomings of the prior art are overcome and additional advantages are provided through the provision of a phase-locked-loop (PLL) circuit, that includes: a differential phase-frequency detector, a charge pump and at least one logical gate disposed therebetween for providing cancellation of pulses of a substantially equivalent value output by the detector to the charge pump; wherein the at least one logical gate receives the detector output signals and generates control signals for the charge pump such that the pulses of substantially equivalent value are eliminated.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### TECHNICAL EFFECTS

Advantages of the design provided herein include, without limitation: cancellation logic located between a phase frequency detector (PFD) and charge pump removes undesired equal value pulses; orthogonal control of charge pump mismatch and charge pump gain; digital cancellation circuitry is virtually independent of process-temperature-voltage (PVT) variations; undesired equal value pulses are removed at the source; simple and efficient design; there is a significant reduction of area and power consumption; and, a 3^{rd} order loop filter is not required to damp reference spurs. Further, the design is suitable for very wideband PLLs because the (analog based) prior-art methods may exhibit operational difficulties in PLL rail-to-rail performance providing sufficiently suppressed charge feed-through.

As a result of the summarized invention, technically we have achieved a solution which a computer program product stored on machine readable media, including instructions for implementing a phase-locked-loop (PLL) circuit, is provided. The product includes instructions for: providing a differential phase-frequency detector, a charge pump and at least one logical gate of at least one of a NAND, NOR, AND, OR, NOT, XOR, XNOR gate disposed therebetween for providing cancellation of pulses of a substantially equivalent value output by the detector to the charge pump; and an extension of the charge pump that provides for an orthogonal adjustment of the charge pump mismatch and the charge pump gain; wherein the at least one logical gate receives the detector output signals and generates control signals for the charge pump such that the pulses of substantially equivalent value are eliminated; wherein when a long pulse is output a logical value of the long pulse is equivalent to that of an inverted short pulse. When the long pulse output (e.g. upp in FIG. 1) is combined by use of a logical gate (e.g. an AND-gate) with the inverted short pulse output (e.g. inversion of dnp in FIG. 1), the effect is that only the actual phase difference—defined as upp-pulse width minus (non-inverted) dnp-pulse width—is fed to the charge pump and hence the undesired equal value pulse was canceled or filtered out.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 depicts an embodiment of a prior art H-brige charge pump of a PLL circuit and associated signals generated by the PLL's PFD used to control the charge pump;

FIG. 2 illustrates a prior-art charge pump with unity gain buffers;

FIG. 3 provides a first embodiment of a circuit for canceling equal value pulses in order to reduce static phase errors and reference spurs;

FIG. 4A and FIG. 4B, collectively referred to as FIG. 4, depict a plurality of charge pump control signals for a prior art PLL circuit design and the same signals for a circuit design according to the teachings herein;

FIG. 5 through FIG. 7 depict aspects of performance of the PLL circuit according to the teachings herein; and

FIG. 8 depicts a phase frequency detector with reset paths generating equal value pulses.

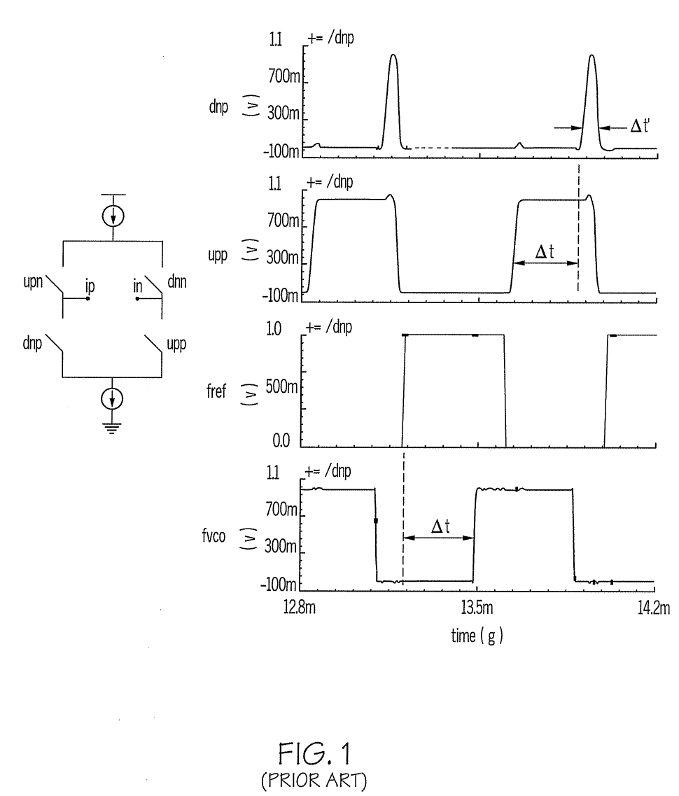

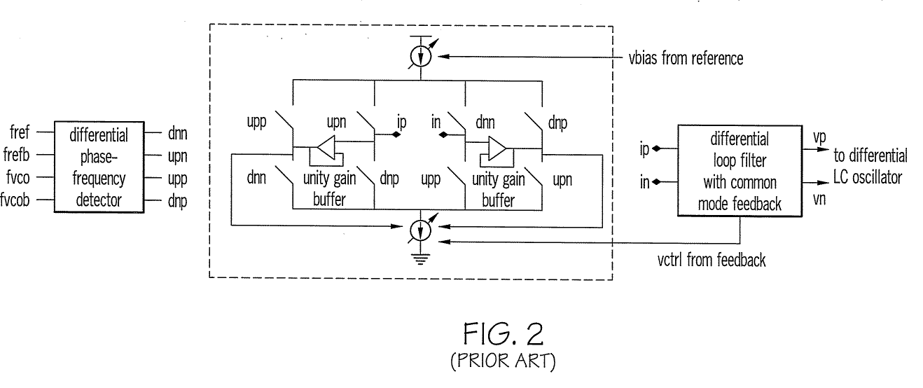

The detailed description explains the preferred embodiments of the invention, together with advantages and features, by way of example with reference to the drawings.

### DETAILED DESCRIPTION OF THE INVENTION

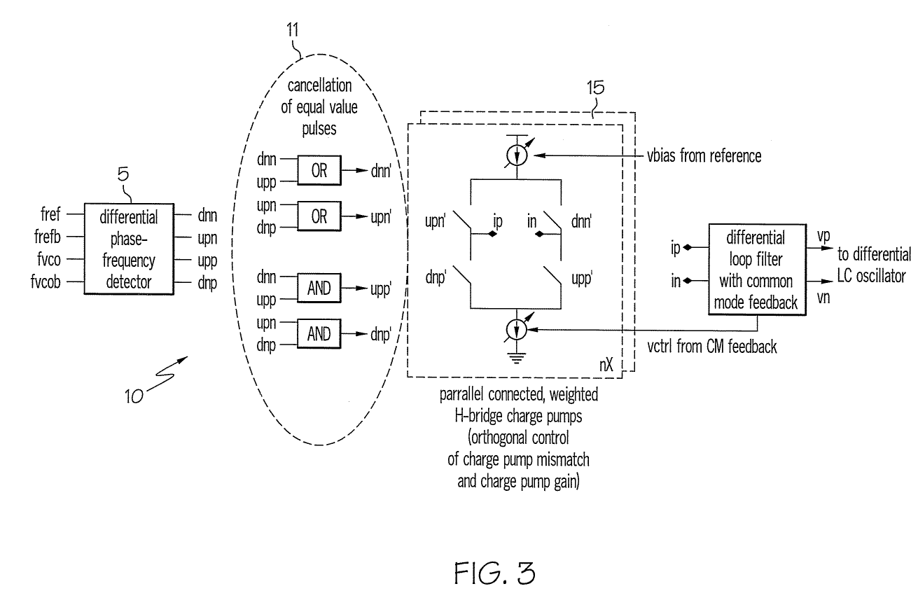

Disclosed is a design for a phase-locked-loop (PLL) circuit that addresses charge feed-through and charge pump mismatch effects. The design may be applied to delay-locked-loop (DLL) circuits as well. For convenience, an exemplary embodiment is provided in FIG. 3.

In FIG. 3, aspects of a circuit 10 for cancellation of pulses of substantially equivalent value in order to reduce static phase errors and reference spurs is depicted. The circuit 10 applies logic 11 between a phase-frequency detectors (PFD) 5 and a charge pump 15. The logic 11 conditions control signals of the charge pump 15 in such a way that none of the switches for the charge pump 15 are closed simultaneously. Additionally, a core of the charge pump 15 is extended with an orthogonal adjustment of a gain for the charge pump 15 and a mismatch for the charge pump 15. The tail current source widths in the charge pump units 15 are further subdivided into binary weighted units (indicated by an arrow in the tail current source symbol in FIG. 3) that can be individually turned on or off by means of a binary code word in order to compensate for potential charge pump mismatches (that is, different sourcing and sinking). Moreover, the individual charge pump units can be switched in parallel in order to increase or decrease the charge pump gain (the more units are switched in parallel, the higher the charge pump gain). The charge pump unit switching is based on a temperature code word to avoid glitches while changing the charge pump gain. The adjustment of the charge pump gain by means of the temperature code word and the charge pump mismatch by means of the binary code word is orthogonal with respect to each other. This means that a potential charge pump mismatch can be compensated without necessarily changing the charge pump gain and vice versa. The combination of the two code words to orthogonally adjust the charge pump gain and charge pump mismatch is termed a “hybrid binary-temperature” code word.

The circuit 10 shown in FIG. 3 includes other loop components (PFD, regular part of CP, loop filter). In this example, the circuit includes only two OR and two AND gates that are fed by the differential PFD outputs upp, upn, dnp, dnn and provide at their outputs the control signals upp′, upn′, dnp′, dnn′.

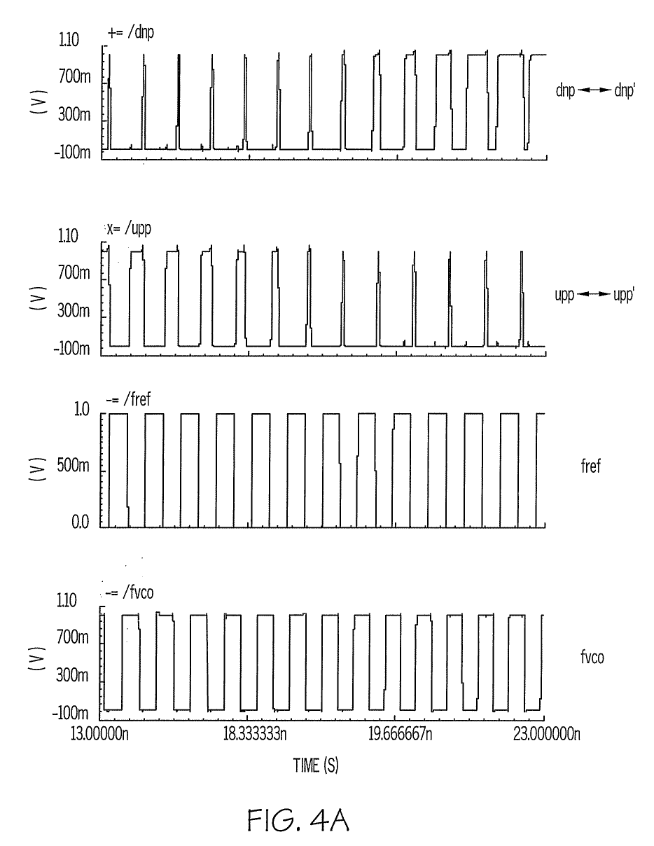

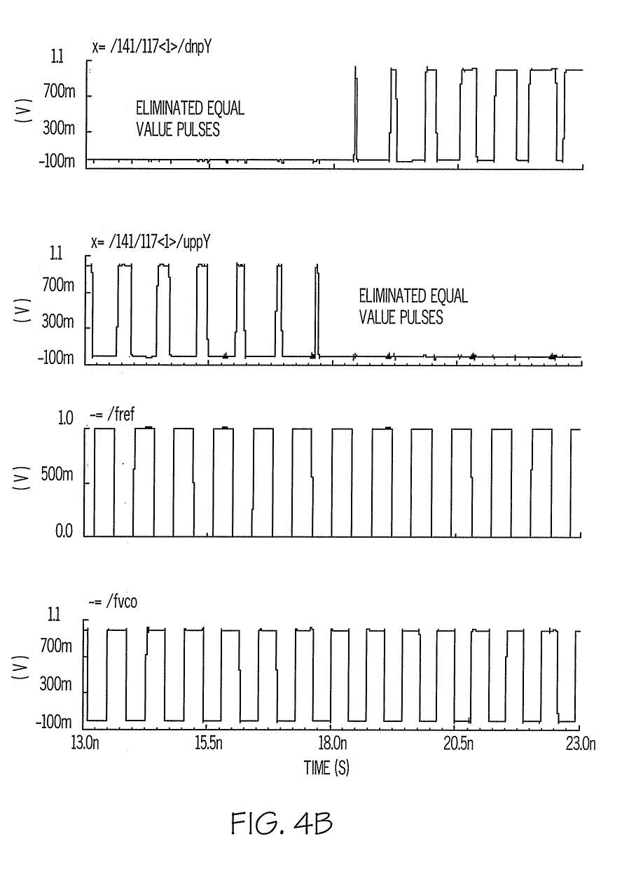

Depending on the circuit design, other logic gates may be employed. For example, NAND, NOR, AND, OR, NOT, XOR, XNOR and other designs of logic gates may be used as determined appropriate. Simulation of performance shows this cancellation circuit is very efficient as illustrated in FIG. 4.

FIG. 4A shows the prior art system that does not include cancellation pulses of substantially equivalent value, while FIG. 4B provides signals for cancellation techniques disclosed herein.

In FIG. 4A, prior art signals without cancellation circuitry are depicted. The equivalent pulses are clearly visible at the upp and dnp traces. Note that the equivalent value pulses change from dnp to upp because the signal f_{vco} is frequency chirp-modulated in this example. In FIG. 4B, results for an embodiment with cancellation enabled are depicted. The regions where the equal value pulses are cancelled are indicated in the timing diagram. This timing diagram is based on transistor level simulations. The signals include a reference signal (f_{ref}), a divided VCO signal (f_{vco}) and charge pump control signals (dnp, dnp′ and upp, upp′).

Instead of trying to remove as much mismatch and asymmetries as possible, the teachings herein provide for elimination of the problem at a source. That is, because it is not possible to eliminate reset pulses within the PFD 5, the circuit 10 provided herein includes a design for canceling short reset pulses by incorporation of additional circuitry (or in some embodiments, logic 11 (such as where the teachings are implemented in software)) located between the output of the PFD 5 and the input of the charge pump 15.

Digital implementation of the logic 11 provides advantages over the prior-art. For example, the teachings herein have the advantage of having performance characteristics that are almost independent of process and temperature variations. Moreover, power consumption and silicon area is negligible compared with the prior-art circuit.

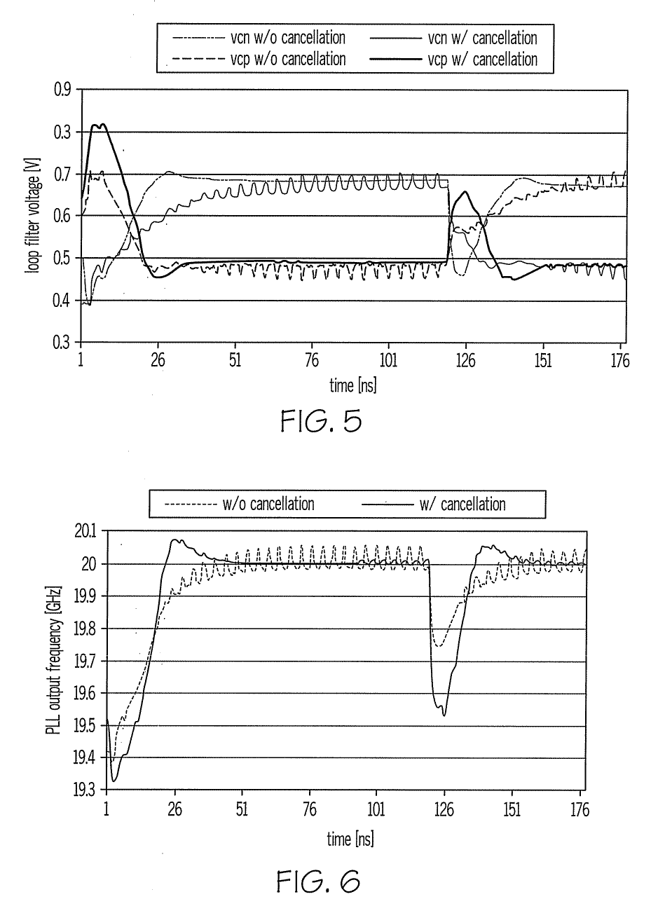

FIG. 5 through FIG. 7 demonstrate impact of the design provided herein on overall PLL performance. The illustrations of performance are based on transistor-level simulations (12S0, nominal corner, 65° C.).

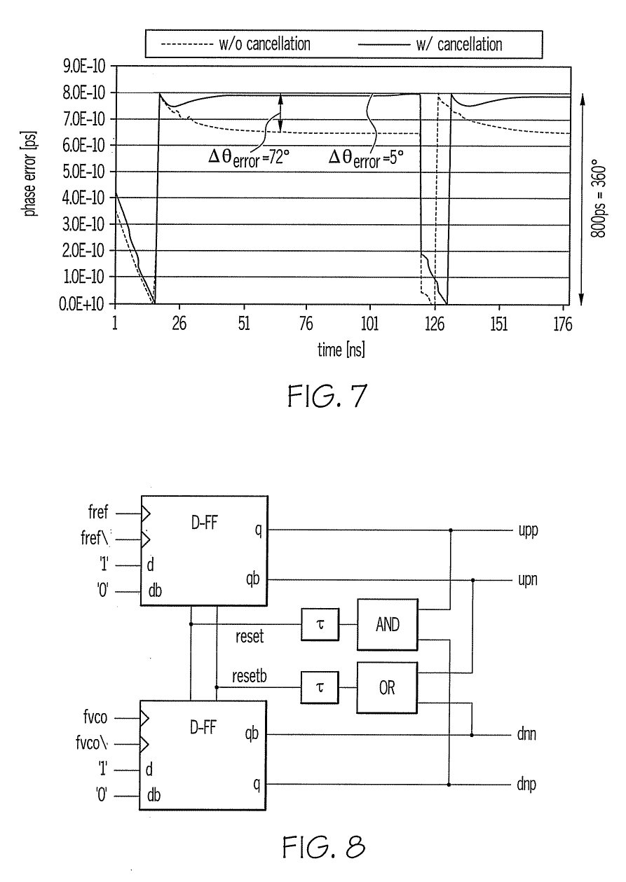

FIG. 5 depicts differential loop filter signals. At 120 nanoseconds (ns), a phase step of 20% T_{ref} (that is, a reference signal period) is applied to determine the closed loop bandwidth. A wideband LC-PLL topology running at 20 GHz with a 1/16-divider is used in this example. To demonstrate the performance benefit of the proposed method, the curves of the PLL characteristics are plotted with enabled (solid curves) and disabled (slightly dashed curves) cancellation technique. FIG. 5 shows the differential loop filter voltages. The period of time from 0 ns to 120 ns represents the transient characteristic of the PLL. In the locked state of the PLL at 120 ns, a phase step of about 20% of T_{ref} has been applied to the reference signal in order to determine the PLL's bandwidth in the transient state. This simulation setup is common to FIG. 5 through FIG. 7. While the PLL with the cancellation technique provided herein shows relatively smooth characteristics of the loop filter voltages, the effect of the missing cancellation technique can easily be recognized by the superimposed ripples at the slightly dashed curves. These ripples also translate to the output frequency as can be seen in FIG. 6. In the spectral domain, these ripples would lead to reference spurs that degrade the phase noise and jitter performance of the PLL. The most important plot however is shown in FIG. 7, which displays the phase error (that is, a phase difference of the divided VCO signal and the reference signal) at the input of the phase frequency detector, measured in picoseconds (ps). The period of the reference frequency in this example is about 800 ps (at 360°).

Owing to the cancellation technique provided herein, static phase error has been improved from about 72° to a value smaller than about 5°, which provides a significantly positive impact on the spectral purity. The transistor-level simulation results provided herein clearly demonstrate some of the advantages of the design provided herein.

Advantages of the design provided herein include, without limitation: cancellation logic located between PFD and charge pump removes undesired equal value pulses; orthogonal control of charge pump mismatch and charge pump gain; digital cancellation circuitry is virtually independent of process-temperature-voltage (PVT) variations; undesired equal value pulses are removed at the source; simple and efficient design; there is a significant reduction of area and power consumption; and, a 3^{rd} order loop filter is not required to damp reference spurs. Further, the design is suitable for very wideband PLLs because the (analog based) prior-art methods may exhibit operational difficulties in PLL rail-to-rail performance providing sufficiently suppressed charge feed-through.

The capabilities of the present invention can be implemented in software, firmware, hardware or some combination thereof.

As one example, one or more aspects of the present invention can be included in an article of manufacture (e.g., one or more computer program products) having, for instance, computer usable media. The media has embodied therein, for instance, computer readable program code means for providing and facilitating the capabilities of the present invention. The article of manufacture can be included as a part of a computer system or sold separately.

Additionally, at least one program storage device readable by a machine, tangibly embodying at least one program of instructions executable by the machine to perform the capabilities of the present invention can be provided.

The flow diagrams depicted herein are just examples. There may be many variations to these diagrams or the steps (or operations) described therein without departing from the spirit of the invention. For instance, the steps may be performed in a differing order, or steps may be added, deleted or modified. All of these variations are considered a part of the claimed invention.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A phase-locked-loop (PLL) circuit, comprising:
a differential phase-frequency detector, a charge pump and at least one logical gate disposed therebetween for providing cancellation of pulses of a substantially equivalent value output by the detector to the charge pump;
wherein the at least one logical gate receives the detector output signals and generates control signals for the charge pump such that the pulses of substantially equivalent value are eliminated.

2. The PLL circuit as in claim 1, wherein the logical gate comprises at least one of a NAND, NOR, AND, OR, NOT, XOR, XNOR gate.

3. The PLL circuit as in claim 1, wherein when a long pulse is output a logical value of the long pulse is equivalent to that of an inverted short pulse.

4. The PLL circuit as in claim 1, comprising an extension of the charge pump that provides for an orthogonal adjustment of a mismatch in the charge pump mismatch and a gain of the charge pump.

5. The PLL circuit as in claim 4, comprising a hybrid binary-temperature code word for adjusting the gain.

6. The PLL circuit as in claim 4, comprising a programmable tail current source for adjusting the mismatch in an orthogonal direction.

7. A computer program product stored on machine readable media, comprising instructions for implementing a phase-locked-loop (PLL) circuit, the product comprising instructions for:
providing a differential phase-frequency detector, a charge pump and at least one logical gate of at least one of a NAND, NOR, AND, OR, NOT, XOR, XNOR gate disposed therebetween for providing cancellation of pulses of a substantially equivalent value output by the detector to the charge pump; and
an extension of the charge pump that provides for an orthogonal adjustment of a mismatch in the charge pump mismatch and a gain of the charge pump;
wherein the at least one logical gate receives the detector output signals and generates control signals for the charge pump such that the pulses of substantially equivalent value are eliminated;
wherein when a long pulse is output a logical value of the long pulse is equivalent to that of an inverted short pulse.
